(19) United States
(12) Patent Application Publication
(10) Pub. No.: US 2026/0230110 A1
(43) Pub. Date: Aug. 6, 2026

(54) DETERMINATION DEVICE AND DETERMINATION METHOD

(71) Applicant: SUMITOMO ELECTRIC INDUSTRIES, LTD., Osaka-shi, Osaka (JP)

(72) Inventors: Kanata NISHIDA, Osaka-shi, Osaka (JP); Masato IZAWA, Osaka-shi, Osaka (JP); Isao KATO, Osaka-shi, Osaka (JP)

(73) Assignee: SUMITOMO ELECTRIC INDUSTRIES, LTD., Osaka-shi, Osaka (JP)

(21) Appl. No.: 19/149,567

(22) PCT Filed: Jan. 12, 2024
(86) PCT No.: PCT/JP2024/000518

§ 371 Date: Jul. 21, 2025

(30) Foreign Application Priority Data
Feb. 22, 2023 (JP) 2023-025672

(51) Int. Cl. H04B 3/46

(52) U.S. Cl. CPC H04B 3/46

(57) ABSTRACT

A determination device includes a signal output circuit configured to output, to a transmission line, a measurement signal having a frequency component, a signal reception circuit configured to receive, from the transmission line, a response signal including a signal resulting from reflection of the measurement signal, an acquisition circuit configured to acquire a plurality of evaluation values based on at least one of an amplitude and a phase of the response signal received by the signal reception circuit, and a determination circuit configured to determine an abnormality of the transmission line based on a distribution of the evaluation values acquired by the acquisition circuit.

### TECHNICAL FIELD

The present disclosure relates to a determination device and a determination method. The present application claims priority based on Japanese Patent Application No. 2023-025672 filed on Feb. 22, 2023, the entire contents of which are incorporated herein by reference.

### BACKGROUND ART

A technique of predicting breaking of a transmission line has been proposed. For example, a line breaking determination device for an electrical cable as described below has been disclosed in PTL 1 (Japanese Unexamined Patent Application Publication No. 2007-305478). That is, the line breaking determination device for an electrical cable includes an electrical cable consisting of a plurality of electrical wires, an electrical shield layer covering the plurality of electrical wires, and a sheath covering the electrical shield layer. The line breaking determination device for an electrical cable also includes a line breaking determination line consisting of a conductor line provided in the electrical shield layer and an insulation layer at an outer periphery of the conductor line. The line breaking determination device for an electrical cable also includes a voltage source electrically connected to the conductor line, a first detector electrically connected to the conductor line, and a second detector electrically connected to the electrical shield layer.

### CITATION LIST

### Patent Literature

PTL 1: Japanese Unexamined Patent Application Publication No. 2007-305478

### SUMMARY OF INVENTION

A determination device according to the present disclosure includes a signal output unit configured to output, to a transmission line, a measurement signal having a frequency component, a signal reception unit configured to receive, from the transmission line, a response signal including a signal resulting from reflection of the measurement signal, an acquisition unit configured to acquire a plurality of evaluation values based on at least one of an amplitude and a phase of the response signal received by the signal reception unit, and a determination unit configured to determine an abnormality of the transmission line based on a distribution of the evaluation values acquired by the acquisition unit.

An aspect of the present disclosure can be implemented not only as the determination device including such a characteristic processing unit but also as a program causing a computer to execute such characteristic processing, as a semiconductor integrated circuit in which part or the entirety of the determination device is implemented, or as a system including the determination device.
Determination

### BRIEF DESCRIPTION OF DRAWINGS

FIG. 1 illustrates a configuration of a communication system according to an embodiment of the present disclosure.

FIG. 2 illustrates a configuration of a relay device according to the embodiment of the present disclosure.

FIG. 3 illustrates an example of time-dependent variation of a frequency distribution F1 generated by a processing unit in the relay device according to the embodiment of the present disclosure.

FIG. 4 illustrates another example of the time-dependent variation of the frequency distribution F1 generated by the processing unit in the relay device according to the embodiment of the present disclosure.

FIG. 5 illustrates corresponding relationships between distances Lop and Lsh and phase differences θop and θsh calculated by the processing unit in the relay device according to the embodiment of the present disclosure.

FIG. 6 illustrates corresponding relationships between the distances Lop and Lsh and the phase differences θop and θsh calculated by the processing unit in the relay device according to the embodiment of the present disclosure.

FIG. 7 illustrates another example of the time-dependent variation of the frequency distribution F1 generated by the processing unit in the relay device according to the embodiment of the present disclosure.

FIG. 8 illustrates an example of the frequency distribution F1 generated by the processing unit in the relay device according to the embodiment of the present disclosure.

FIG. 9 illustrates another example of the frequency distribution F1 generated by the processing unit in the relay device according to the embodiment of the present disclosure.

FIG. 10 illustrates another example of the frequency distribution F1 generated by the processing unit in the relay device according to the embodiment of the present disclosure.

FIG. 11 illustrates an example of time-dependent variation of a frequency distribution F2 generated by a processing unit in the relay device according to the embodiment of the present disclosure.

FIG. 12 illustrates another example of the time-dependent variation of the frequency distribution F2 generated by the processing unit in the relay device according to the embodiment of the present disclosure.

FIG. 13 illustrates another example of the time-dependent variation of the frequency distribution F2 generated by the processing unit in the relay device according to the embodiment of the present disclosure.

FIG. 14 illustrates an example of the frequency distribution F2 generated by the processing unit in the relay device according to the embodiment of the present disclosure.

FIG. 15 illustrates another example of the frequency distribution F2 generated by the processing unit in the relay device according to the embodiment of the present disclosure.

FIG. 16 illustrates another example of the frequency distribution F2 generated by the processing unit in the relay device according to the embodiment of the present disclosure.

FIG. 17 illustrates another example of the frequency distribution F1 generated by the processing unit in the relay device according to the embodiment of the present disclosure.

FIG. 18 is a flowchart defining an example of an operation procedure when the relay device according to the embodiment of the present disclosure performs a determination process.

FIG. 19 is a flowchart defining the example of the operation procedure when the relay device according to the embodiment of the present disclosure performs the determination process.

FIG. 20 is a flowchart defining the example of the operation procedure when the relay device according to the embodiment of the present disclosure performs the determination process.

### DETAILED DESCRIPTION

### Problems to be Solved by Present Disclosure

A technique surpassing the technique described in PTL 1 and enabling more exact determination of an abnormality of a transmission line is desired.

The present disclosure is made to solve the above-described problem and aiming at providing a determination device and a determination method that enable more exact determination of an abnormality of a transmission line.

### Advantageous Effects of Present Disclosure

According to the present disclosure, the abnormality of the transmission line can be more exactly determined.

First, the contents of an embodiment of the present disclosure are listed and described.
(1) A determination device according to the embodiment of the present disclosure includes a signal output unit configured to output, to a transmission line, a measurement signal having a frequency component, a signal reception unit configured to receive, from the transmission line, a response signal including a signal resulting from reflection of the measurement signal, an acquisition unit configured to acquire a plurality of evaluation values based on at least one of an amplitude and a phase of the response signal received by the signal reception unit, and a determination unit configured to determine an abnormality of the transmission line based on a distribution of the evaluation values acquired by the acquisition unit.

With such a configuration in which the measurement signal having a frequency component is output to the transmission line, the evaluation values based on the response signal received from the transmission line are acquired, and the abnormality of the transmission line is determined based on the distribution of the acquired evaluation values, the abnormality can be determined based on a statistic of the evaluation values having been acquired a plurality of times. Thus, reliability in determination of the abnormality can be improved. Accordingly, the abnormality of the transmission line can be more exactly determined.
(2) In (1) described above, the determination unit may determine the abnormality of the transmission line based on time-dependent variation of a statistic indicated by the distribution.

With such a configuration, for example, the occurrences and progression of the abnormality can be more exactly determined based on the variation of the statistic with reference to the statistic when the abnormality of the transmission line does not occur.
(3) In (1) or (2) described above, the determination unit may determine the abnormality of the transmission line based on a correlation between the distribution and a predetermined distribution.

With such a configuration, for example, the occurrences and progression of the abnormality can be more exactly determined based on the correlation with the distribution when the abnormality of the transmission line does not occur.
(3) In any one of (1) to (3) described above, the determination unit may further determine a type of the abnormality occurring in the transmission line based on the distribution.

With such a configuration, maintenance such as replacement of the transmission line can be efficiently planned depending on the determined type of the abnormality.
(5) In (4) described above, the determination unit may determine, as the type of the abnormality occurring in the transmission line, at least one of breaking of the transmission line, a short circuit of the transmission line, and degradation of the transmission line.

With such a configuration, whether to replace the transmission line can be exactly determined depending on the determined type of the abnormality.
(6) In any one of (1) to (5) described above, the acquisition unit may acquire first evaluation values being the evaluation values based on the amplitude and second evaluation values being the evaluation values based on the phase. In this case, the determination unit may determine the abnormality of the transmission line based on a distribution of the first evaluation values and a distribution of the second evaluation values.

With such a configuration, the abnormality of the transmission line can be more exactly determined. Furthermore, for example, as the abnormality of the transmission line, the short circuit and degradation of the transmission line can be determined, and the breaking and the degradation of the transmission line can be determined.
(7) In (6) described above, the determination unit may determine, as types of the abnormality occurring in the transmission line, the breaking of the transmission line, the short circuit of the transmission line, and the degradation of the transmission line based on the distribution of the first evaluation values and the distribution of the second evaluation values.

With such a configuration, the breaking, the short circuit, and the degradation of the transmission line can be exactly determined by using the distribution of the first evaluation values and the distribution of the second evaluation values.
(8) In (6) or (7) described above, the determination unit may determine a position of the abnormality occurring in the transmission line based on the distribution of the second evaluation values.

With such a configuration, the position of the abnormality of the transmission line can be exactly determined by using the distribution of the second evaluation values.
(9) A determination method according to the embodiment of the present disclosure includes outputting, to a transmission line, a measurement signal having a frequency component, receiving, from the transmission line, a response signal including a signal resulting from reflection of the measurement signal, acquiring an evaluation value based on at least one of an amplitude and a phase of the received response signal, and determining an abnormality of the transmission line based on a distribution of the acquired evaluation value.

With such a method in which the measurement signal having a frequency component is output to the transmission line, the evaluation values based on the response signal received from the transmission line are acquired, and the abnormality of the transmission line is determined based on the distribution of the acquired evaluation values, the abnormality can be determined based on a statistic of the evaluation values having been acquired a plurality of times. Thus, reliability in determination of the abnormality can be improved. Accordingly, the abnormality of the transmission line can be more exactly determined.

Hereinafter, an embodiment of the present disclosure will be described with reference to the drawings. In the drawings, the same or corresponding parts are denoted by the same reference numerals, thereby omitting the description of the same or corresponding parts. At least parts of the embodiment to be described below may be arbitrarily combined.

### [Configuration and Basic Operation]

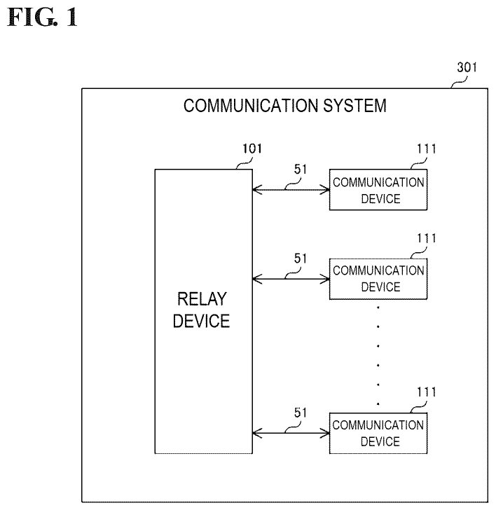

FIG. 1 illustrates a configuration of a communication system according to the embodiment of the present disclosure. Referring to FIG. 1, a communication system 301 includes a relay device 101 and a plurality of communication devices 111.

The relay device 101 is connected to each of the communication devices 111 via a transmission line 51 for communication in a one-to-one manner. In more detail, the transmission line 51 includes a cable portion and connector portions provided at a first end and a second end of the cable portion. The connector portion provided at the first end of the cable portion is connected to the relay device 101. The connector portion provided at the second end of the cable portion is connected to the communication device 111. The transmission line 51 may be a solid wire or paired wires. The transmission line 51 is, for example, an Ethernet (registered trademark) cable.

The communication system 301 is mounted on, for example, a vehicle. In this case, the communication device 111 is, for example, an on-vehicle electronic control unit (ECU). The communication system 301 may be used in, for example, a home network or factory automation.

The relay device 101 can communicate with the communication device 111. The relay device 101 is configured to perform a relay process that relays, for example, information communicated between the plurality of communication devices 111 connected to the different transmission lines 51. The relay device 101 also functions as a determination device to perform a determination process that, for example, periodically determines an abnormality of the transmission lines 51. In more detail, due to degradation, the transmission lines 51 may break or may be short-circuited with other wires or the ground. The relay device 101 determines breaking, a short circuit, and the like of the transmission line 51 as the abnormality of the transmission line 51.

### [Relay Device]

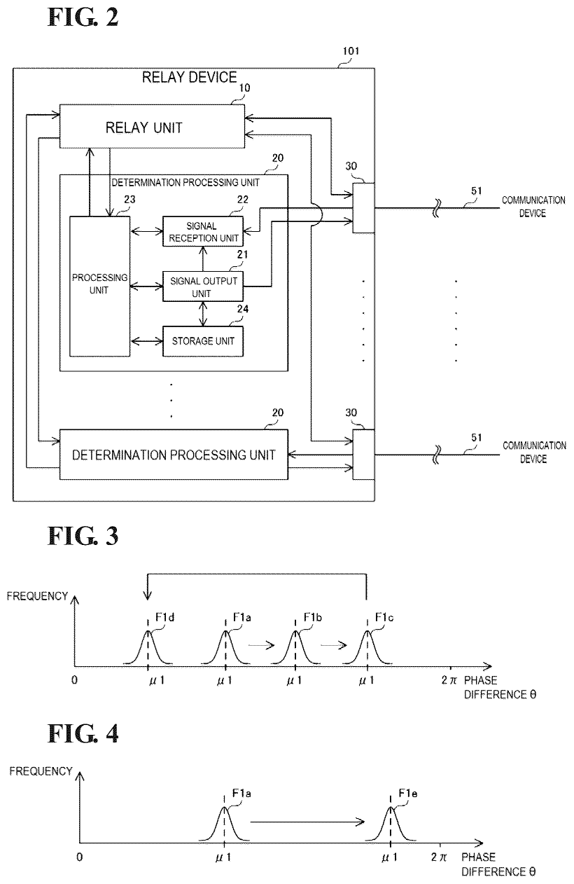

FIG. 2 illustrates a configuration of the relay device according to the embodiment of the present disclosure. Referring to FIG. 2, the relay device 101 includes a relay unit 10, a plurality of determination processing units 20, and a plurality of communication ports 30. The determination processing units 20 each include a signal output unit 21, a signal reception unit 22, a processing unit 23, and a storage unit 24. The processing unit 23 is an example of an acquisition unit and also an example of a determination unit. A subset or all of the relay unit 10, the signal output unit 21, the signal reception unit 22, and the processing unit 23 may be implemented by, for example, processing circuitry including one or a plurality of processors. The storage unit 24 is, for example, non-volatile memory included in the above-described processing circuitry. The communication ports 30 are, for example, connectors or terminals. The connector portion of the transmission line 51 is connected to each of the communication ports 30.

For example, an end portion of the transmission line 51 on the communication device 111 side is impedance matched. This end portion of the transmission line 51 is not necessarily exactly impedance matched.

The relay device 101 outputs measurement signals having a frequency component to the transmission lines 51 and receives, from the transmission lines 51, response signals including signals resulting from reflection of the measurement signals. The relay device 101 acquires a plurality of evaluation values EV based on the amplitude and phase of the received response signals. The relay device 101 determines the abnormality of the transmission lines 51 based on a distribution of the acquired evaluation values EV. The details of processing in the relay device 101 will be described later.

### <Relay Unit>

The relay unit 10 performs the relay process that relays frames between the communication devices 111. In more detail, the relay unit 10 sends a frame received from a certain communication device 111 via the corresponding transmission line 51 and the corresponding communication port 30 to the other communication device 111 in accordance with destination information such as a destination IP address, a MAC address, and a message ID of the frame via the corresponding communication port 30 and the corresponding transmission line 51. That is, the relay unit 10 sends and receives communication signals including the frames to and from the communication devices 111 via the communication ports 30 and the transmission lines 51.

### <Determination Processing Unit>

For example, the relay device 101 includes the same number of the determination processing units 20 as the number of the communication ports 30. In more detail, the determination processing units 20 are provided corresponding to the communication ports 30 and configured to perform the determination process that determines the abnormality of the transmission lines 51 connected to the corresponding communication ports 30. Hereinafter, the determination process performed by one of the determination processing units 20 in the relay device 101 is described as a typical determination process.

### (Signal Output Unit)

The signal output unit 21 is configured to output a measurement signal having a frequency component to the transmission line 51. In more detail, the signal output unit 21 outputs an alternating current signal, a pulse signal, or a frequency sweep signal to the transmission line 51 as the measurement signal.

For example, in a period during which the relay process via the transmission line 51 is not performed by the relay unit 10, the signal output unit 21 outputs the measurement signal to the transmission line 51 via the corresponding communication port 30.

In more detail, the relay unit 10 outputs to the processing unit 23 period information indicating a period during which the relay process via the transmission line 51 is not performed.

In response to the period information from the relay unit 10, the processing unit 23 determines a determination period T1 during which the determination process is performed based on the received period information and outputs a determination instruction indicating the determined determination period T1 to the signal output unit 21 and the signal reception unit 22.

In response to the determination instruction from the processing unit 23, the signal output unit 21 outputs the measurement signal to the transmission line 51 via the corresponding communication port 30 when a starting time of the determination period T1 indicated by the received determination instruction arrives until the determination period T1 expires.

As an example, the signal output unit 21 outputs a measurement signal being sinusoidal waves of a frequency f to the transmission line 51. For example, the storage unit 24 stores N digital signals Ds1 acquired by performing digital conversion on sinusoidal waves for a plurality of periods. That is, the storage unit 24 stores the digital signals Ds1 of N samples corresponding to the sinusoidal waves. N is an integer of two or greater.

The signal output unit 21 includes a digital-to-analog (DA) conversion unit. The signal output unit 21 acquires a digital signal Ds1 from the storage unit 24 at output timing in accordance with the period of an operation clock of the DA conversion unit when the starting time of the determination period T1 arrives until the determination period T1 expires. Furthermore, the signal output unit 21 outputs to the transmission line 51 via the communication port 30 the measurement signal of the frequency f generated by performing the analog conversion on the digital signal Ds 1 with the DA conversion unit. Furthermore, the signal output unit 21 outputs the acquired digital signal Ds1 to the processing unit 23. For example, as will be described later, the frequency f is set in accordance with a length Lc of the transmission line 51.

The signal output unit 21 may include, for example, a signal generation unit such as a direct digital synthesizer (DDS). In this case, the signal output unit 21 outputs the sinusoidal waves generated by the signal generation unit to the transmission line 51 via the communication port 30.

### (Signal Reception Unit)

The signal reception unit 22 is configured to receive from the transmission line 51 the response signal including a signal resulting from the reflection of the measurement signal. That is, the signal reception unit 22 receives from the transmission line 51 via the corresponding communication port 30 the response signal including the measurement signal output by the signal output unit 21 and a reflection signal being a signal resulting from the reflection of the measurement signal.

In more detail, in response to the determination instruction from the processing unit 23, the signal reception unit 22 receives the response signal from the transmission line 51 via the corresponding communication port 30 when the starting time of the determination period T1 indicated by the received determination instruction arrives until the determination period T1 expires.

The signal reception unit 22 includes an analog-to-digital (AD) conversion unit. The signal reception unit 22 samples the response signals received from the transmission line 51 with the AD conversion unit during the determination period T1, thereby to generate a digital signal Ds2 of N samples. The signal reception unit 22 outputs the generated digital signal Ds2 to the processing unit 23.

### (Processing Unit)

The processing unit 23 calculates the evaluation values EV based on the amplitude and phase of the response signals received by the signal reception unit 22. The processing unit 23 performs the determination process based on the distribution of the calculated evaluation values EV.

For example, the processing unit 23 calculates the evaluation values EV based on the amplitude and phase of the measurement signals and the amplitude and phase of reflection signals included in the response signals.

In more detail, the processing unit 23 generates a digital signal Ds3 indicating the reflection signal by subtracting the component of the digital signal Ds1 received from the signal output unit 21 from the digital signal Ds2 received from the signal reception unit 22. The processing unit 23 calculates an evaluation value EV relating to a reflection coefficient R being the ratio of the reflection signal to the measurement signal represented by expression (1) below based on the digital signal Ds1 indicating the measurement signal and the digital signal Ds3 indicating the reflection signal.

$$[ Math . 1 ]$$

$$R = \frac{V 2}{V 1} = A \times e \hat{} ( - j θ ) \qquad ( 1 )$$

Where V1 is a voltage level of the measurement signal, V2 is a voltage level of the reflection signal, e is a Napier's constant, j is an imaginary unit, θ is a phase difference between the measurement signal and the reflection signal, and A is an amplitude ratio obtained by dividing the amplitude of the reflection signal by the amplitude of the measurement signal.

### Determination Example 1

The processing unit 23 calculates the phase difference θ as the evaluation value EV. In more detail, the processing unit 23 calculates, for example, the phase difference θ for each period of the measurement signal based on the digital signal Ds1 indicating the measurement signal and the digital signal Ds3 indicating the reflection signal and stores the calculated phase difference θ in the storage unit 24. The phase difference θ is 0° to 360°. The phase difference θ is an example of a second evaluation value.

For example, the processing unit 23 generates, for each determination period T1, a frequency distribution F1 being a distribution of the phase difference θ in the determination period T1 and determines abnormality of the transmission line 51 based on the generated frequency distribution F1.

FIG. 3 illustrates an example of time-dependent variation of the frequency distribution F1 generated by the processing unit in the relay device according to the embodiment of the present disclosure. In FIG. 3, the horizontal axis represents the phase difference θ [rad], and the vertical axis represents the frequency. FIG. 3 illustrates frequency distributions F1a, F1b, F1c, and F1d that vary depending on elapse of time. The frequency distribution Fla is the frequency distribution F1 of the phase difference θ when the abnormality of the transmission line 51 does not occur. The frequency distribution F1b is the frequency distribution F1 of the phase difference θ when the transmission line 51 is degraded. The frequency distribution F1c is the frequency distribution F1 of the phase difference θ when the degradation of the transmission line 51 is progressed. The frequency distribution F1d is the frequency distribution F1 of the phase difference θ when the transmission line 51 breaks.

Referring to FIG. 3, an average μ1 of the phase difference θ indicated by the frequency distribution F1 increases when the transmission line 51 degrades. When the transmission line 51 breaks, the average μ1 is a value corresponding to a line breaking position. In more detail, a phase difference θop being the phase difference θ when the transmission line 51 breaks is represented by expression (2) below.

$$[ Math . 2 ]$$

$$θ op = \frac{4 π Lopf \sqrt{ε r}}{c} \qquad ( 2 )$$

Where Lop is a distance [m] from an end portion of the transmission line 51 on the relay device 101 side to the line breaking position, Lop is zero or greater and Lc or smaller, c is the speed of light [m/seC], and er is a relative dielectric constant of the transmission line 51.

Depending on the magnitude relationship between a characteristic impedance Z1 of the transmission line 51 and a load impedance Z2 of the communication device 111, the average μ1 may increase or reduce due to the degradation of the transmission line 51.

In more detail, the reflection coefficient R is represented by expression (3) below with the characteristic impedance Z1 and the load impedance Z2.

$$[ Math . 3 ]$$

$$R = \frac{Z 2 - Z 1}{Z 2 + Z 1} \qquad ( 3 )$$

When the transmission line 51 degrades, the characteristic impedance Z1 increases. Whether the degradation of the transmission line 51 increases or reduces the phase difference θ is determined depending on whether the increase in the characteristic impedance Z1 increases or reduces the reflection coefficient R. In the communication system 301, the average μ1 is assumed to increase when the transmission line 51 degrades.

FIG. 4 illustrates another example of the time-dependent variation of the frequency distribution F1 generated by the processing unit in the relay device according to the embodiment of the present disclosure. In FIG. 4, the horizontal axis represents the phase difference θ [rad], and the vertical axis represents the frequency. FIG. 4 illustrates frequency distributions Fla and Fle. The frequency distribution F1e is the frequency distribution F1 of the phase difference θ when the transmission line 51 is short-circuited.

Referring to FIG. 4, the average μ1 indicated by the frequency distribution F1 is a value corresponding to a short-circuited position when the transmission line 51 is short-circuited. In more detail, a phase difference θsh being the phase difference θ when the transmission line 51 is short-circuited is represented by expression (4) below.

$$[ Math . 4 ]$$

$$θ sh = \frac{4 π Lshf \sqrt{ε r}}{c} + π \qquad ( 4 )$$

Where Lsh is a distance [m] from the end portion of the transmission line 51 on the relay device 101 side to the short-circuited position, and Lsh is zero or greater and Lc or smaller,

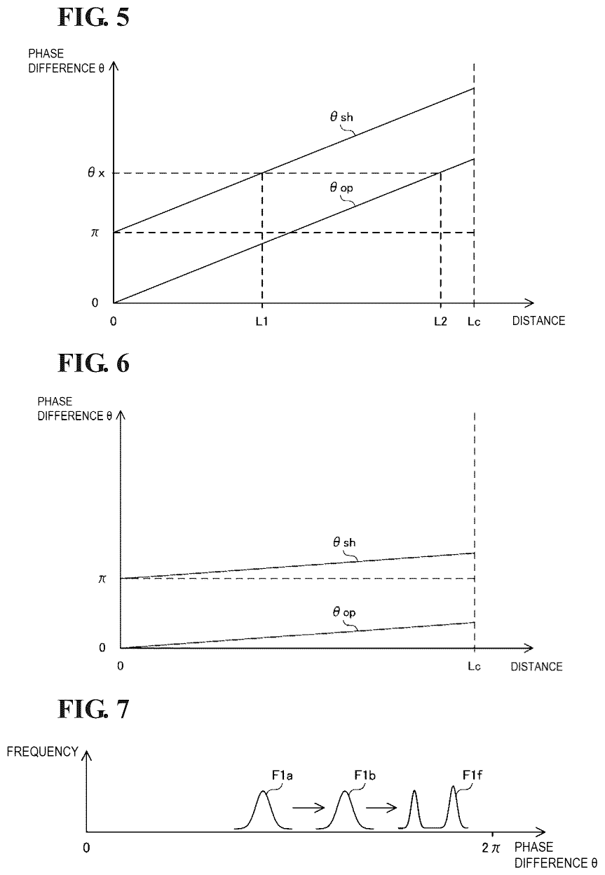

FIGS. 5 and 6 illustrate corresponding relationships between the distances Lop and Lsh and the phase differences θop and θsh calculated by the processing unit in the relay device according to the embodiment of the present disclosure. In FIGS. 5 and 6, the horizontal axis represents the distance [m] from the end portion of the transmission line 51 on the relay device 101 side to an abnormality occurring position, and the vertical axis represents the phase difference θ [rad]. FIG. 5 illustrates the corresponding relationships between the distances Lop and Lsh and the phase differences θop and θsh when the frequency f of the measurement signal is 10 MHz. FIG. 6 illustrates the corresponding relationships between the distances Lop and Lsh and the phase differences θop and Osh when the frequency f of the measurement signal is 1 MHz.

Referring to FIG. 5, when the frequency f is 10 MHz, the minimum value of the phase difference θsh is smaller than the maximum value of the phase difference θop. Accordingly, when, for example, the phase difference θ is a phase difference Ox, it cannot be determined that whether a short circuit occurs at a position of a distance L1 from the end portion of the transmission line 51 on the relay device 101 side or line breaking occurs at a position of a distance L2 from the end portion of the transmission line 51 on the relay device 101 side.

Meanwhile, referring to FIG. 6, when the frequency f is 1 MHz, the minimum value of the phase difference θsh is greater than the maximum value of the phase difference θop. Accordingly, depending on the value of the phase difference θ, it can be determined that whether a short circuit occurs in the transmission line 51 or breaking occurs in the transmission line 51.

Here, the minimum value of the phase difference θsh is x, and the maximum value of the phase difference θop is in the case where the distance Lop in expression (2) above is equivalent to the length Lc of the transmission line 51. Accordingly, in the relay device 101, for determining a short circuit and breaking in the transmission line 51, the frequency f of the measurement signal is set to a value that satisfies expression (5) below.

$$[ Math . 5 ]$$

$$f < \frac{c}{4 Lc \sqrt{ε r}} \qquad ( 5 )$$

FIG. 7 illustrates another example of the time-dependent variation of the frequency distribution F1 generated by the processing unit in the relay device according to the embodiment of the present disclosure. In FIG. 7, the horizontal axis represents the phase difference θ [rad], and the vertical axis represents the frequency. FIG. 7 illustrates the frequency distributions F1a, F1b, and F1f. The frequency distribution F1f is the frequency distribution F1 of the phase difference θ when special abnormality other than the degradation, the short circuit, and the breaking occurs in the transmission line 51. When the special abnormality occurs in the transmission line 51, this means that, for example, the transmission line 51 partially breaks and the sections of a partially breaking portion are repeatedly brought into contact with or separated from each other.

Referring to FIG. 7, left-right symmetry of the shape of the frequency distribution F1 about the average μ1 is reduced when the special abnormality occurs in the transmission line 51.

As has been described with reference to FIGS. 3 to 7, the frequency distribution F1 varies when the abnormality occurs in the transmission line 51. Accordingly, the abnormality of the transmission line 51 can be determined based on the frequency distribution F1.

In more detail, when the processing unit 23 generates the frequency distribution F1, the processing unit 23 performs the determination process based on the time-dependent variation of a statistic indicated by the frequency distribution F1. As an example, as statistics indicated by the frequency distribution F1, the processing unit 23 calculates the average μ1 and a median m1 of the phase difference θ indicated by the frequency distribution F1 and performs the determination process based on the time-dependent variation of the average μ1 and the median m1.

For example, the storage unit 24 stores a reference distribution Fr1 and a reference average ula. The reference distribution Fr1 is the frequency distribution F1 of the phase difference θ when the abnormality of the transmission line 51 does not occur. The reference average ula is the average μ1 indicated by the reference distribution Fr1. The reference distribution Fr1 is generated in advance based on a plurality of phase differences θ calculated before operation of the communication system 301.

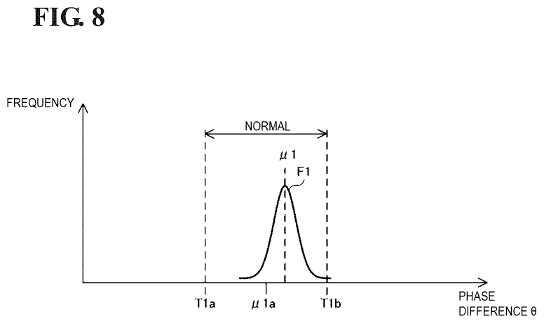

FIG. 8 illustrates an example of the frequency distribution F1 generated by the processing unit in the relay device according to the embodiment of the present disclosure. In FIG. 8, the horizontal axis represents the phase difference θ [rad], and the vertical axis represents the frequency. Referring to FIG. 8, when the processing unit 23 generates the frequency distribution F1, the processing unit 23 compares the average μ1 indicated by the generated frequency distribution F1 with thresholds T1a and T1b set based on the reference distribution Fr1. The processing unit 23 also compares the average μ1 indicated by the frequency distribution F1 with the median m1 indicated by the frequency distribution F1.

For example, the threshold T1a is obtained by subtracting a predetermined value from the reference average ula, and the threshold T1b is obtained by adding a predetermined value to the reference average ula. The threshold T1a may be obtained by, for example, subtracting three times a standard deviation Sy of the reference distribution Fr1 from the reference average ula. The threshold T1b may be obtained by, for example, adding three times the standard deviation Sy to the reference average ula.

The processing unit 23 determines that the abnormality does not occur in the transmission line 51 when the average μ1 is the threshold T1a or greater and the threshold T1b or smaller and an absolute value D1 of the difference between the average μ1 and the median m1 is a predetermined threshold TD1 or smaller. Then, the processing unit 23 stores determination results including the average μ1 in the storage unit 24.

The processing unit 23 may calculate, as the statistics indicated by the frequency distribution F1, the other statistics representing the shape of the frequency distribution F1 such as the standard deviation and the maximum value of the phase difference θ indicated by the frequency distribution F1 and use the calculated other statistics, for example, a mode instead of the median m1.

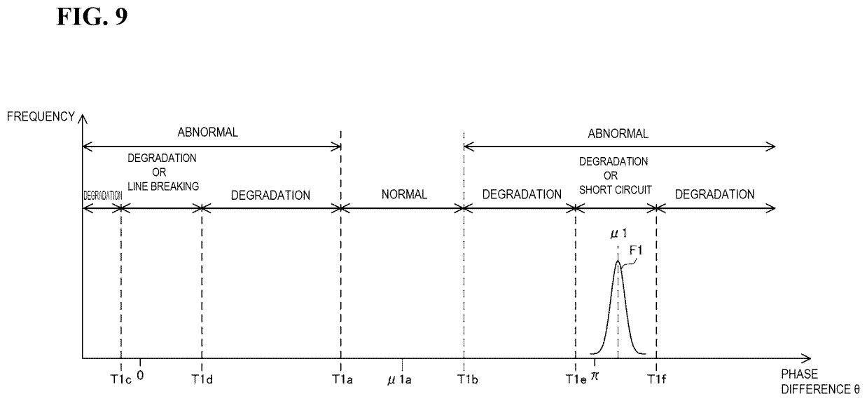

FIG. 9 illustrates another example of the frequency distribution F1 generated by the processing unit in the relay device according to the embodiment of the present disclosure. In FIG. 9, the horizontal axis represents the phase difference θ [rad], and the vertical axis represents the frequency.

Referring to FIG. 9, the processing unit 23 determines that the abnormality occurs in the transmission line 51 when the average μ1 is smaller than the threshold T1a or greater than the threshold T1b.

In this case, the processing unit 23 further determines the types of the abnormality occurring in the transmission line 51 based on the frequency distribution F1. For example, the processing unit 23 determines breaking of the transmission line 51, a short circuit of the transmission line 51, and degradation of the transmission line 51 as the types of the abnormality occurring in the transmission line 51.

In more detail, the processing unit 23 compares the average μ1 with predetermined thresholds T1c, T1d, T1e, and T1f. The threshold T1c is obtained by subtracting a predetermined margin from zero being the minimum value of the phase difference θop illustrated in FIG. 6. The threshold T1d is obtained by adding a predetermined margin to the maximum value of the phase difference θop illustrated in FIG. 6. The threshold T1e is obtained by subtracting a predetermined margin from π being the minimum value of the phase difference θsh illustrated in FIG. 6. The threshold T1f is obtained by adding a predetermined margin to the maximum value of the phase difference θsh illustrated in FIG. 6.

The processing unit 23 determines that the transmission line 51 is short-circuited or degraded when the average μ1 is the threshold T1e or greater and the threshold T1f or smaller. Then, the processing unit 23 stores the determination results including the average μ1 in the storage unit 24.

The processing unit 23 determines that the transmission line 51 breaks or is degraded when the average μ1 is the threshold T1c or greater and the threshold T1d or smaller. Then, the processing unit 23 stores the determination results including the average μ1 in the storage unit 24.

The processing unit 23 determines that the transmission line 51 is degraded in any one of the following cases: the average μ1 is smaller than the threshold T1c; the average μ1 is greater than the threshold T1d and smaller than the threshold T1a; the average μ1 is greater than the threshold T1b and smaller than the threshold T1e; and the average μ1 is greater than the threshold T1f. Then, the processing unit 23 stores the determination results including the average μ1 in the storage unit 24.

For example, the processing unit 23 determines the degree of progression of degradation of the transmission line 51 based on the time-dependent variation of the average μ1 indicated by the frequency distribution F1. In more detail, the processing unit 23 compares the calculated average μ1 with the average μ1 included in the previous determination results when the transmission line 51 is determined to be degraded. Then, the processing unit 23 determines the degree of progression based on the amount of variation by which the calculated average μ1 varies from the average μ1 included in the previous determination results.

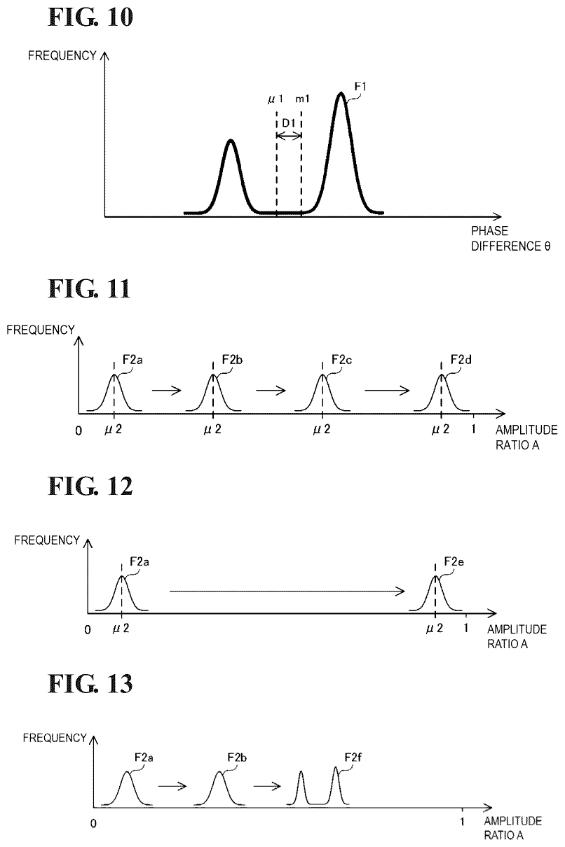

FIG. 10 illustrates another example of the frequency distribution F1 generated by the processing unit in the relay device according to the embodiment of the present disclosure. In FIG. 10, the horizontal axis represents the phase difference θ [rad], and the vertical axis represents the frequency. Referring to FIG. 10, the processing unit 23 determines that the special abnormality occurs in the transmission line 51 when the absolute value D1 of the difference between the average μ1 and the median m1 is greater than the threshold TD1. Then, the processing unit 23 stores the determination results including the average μ1 and the median m1 in the storage unit 24.

For example, when the processing unit 23 determines that the abnormality occurs in the transmission line 51, the processing unit 23 notifies the user of the determination results including the type of the abnormality via the relay unit 10 and the communication device 111.

### (Modification 1)

The processing unit 23 determines the abnormality of the transmission line 51 based on the time-dependent variation of the shape of the frequency distribution F1. For example, the processing unit 23 determines the abnormality of the transmission line 51 based on the correlation between the shape of the frequency distribution F1 and the shape of the reference distribution Fr1.

In more detail, when the processing unit 23 generates the frequency distribution F1, the processing unit 23 acquires the reference distribution Fr1 from the storage unit 24. Then, the processing unit 23 calculates a correlation coefficient C1 indicating the correlation between the generated frequency distribution F1 and the reference distribution Fr1 in accordance with expression (6) below.

$$[ Math . 6 ]$$

$$C 1 = \frac{Sxy}{Sx \times Sy} = \frac{{\sum }_{i = 1}^{n} ( x i - μ 1 ) ( y i - μ 1 a )}{\sqrt{{\sum }_{i = 1}^{n} {( xi - μ 1 )}^{2} {\sum }_{i = 1}^{n} {( y i - μ 1 a )}^{2}}} \qquad ( 6 )$$

Where Sxy is a covariance of the frequency distribution F1 and the reference distribution Fr1, Sx is a standard deviation of the frequency distribution F1, Sy is a standard deviation of the reference distribution Fr1, xi is a frequency of a phase difference θi in the frequency distribution F1, yi is a frequency of a phase difference θi in the reference distribution Fr1, and n is the number of pieces of data of the phase difference θ included in the frequency distribution F1 and the number of pieces of data of the phase difference θ included in the reference distribution Fr1. For example, the phase difference θ in the frequency distribution F1 and the phase difference θ in the reference distribution Fr1 are relative. The phase difference θ in the frequency distribution F1 is corrected such that the position of the skirt of the frequency distribution F1 matches the position of the skirt of the reference distribution Fr1 or the median m1 of the frequency distribution F1 matches the median of the reference distribution Fr1.

When the correlation coefficient C1 is a predetermined threshold TC1 or greater, the processing unit 23 determines that the special abnormality does not occur in the transmission line 51. The threshold TC1 is a value of 0.2 to 1 appropriately set by an application. For example, the threshold TC1 may be 0.7. In contrast, when the correlation coefficient C1 is smaller than the predetermined threshold TC1, the processing unit 23 determines that the special abnormality occurs in the transmission line 51.

The processing unit 23 may perform the determination process based on time-dependent variation of an envelope representing the shape of the frequency distribution F1 instead of calculating the correlation coefficient C1. In more detail, the processing unit 23 determines whether the special abnormality occurs in the transmission line 51 based on a result of comparison between the envelope representing the shape of the frequency distribution F1 and an envelope representing the shape of the reference distribution Fr1.

### Determination Example 2

The processing unit 23 calculates the amplitude ratio A as the evaluation value EV. In more detail, the processing unit 23 calculates, for example, the amplitude ratio A for each period of the measurement signal based on the digital signal Ds1 indicating the measurement signal and the digital signal Ds3 indicating the reflection signal and stores the calculated amplitude ratio A in the storage unit 24. The amplitude ratio A is 0 to 1. The amplitude ratio A is an example of a first evaluation value.

The processing unit 23 generates, for each determination period T1, a frequency distribution F2 being a distribution of the amplitude ratio A in the determination period T1 and determines the abnormality of the transmission line 51 based on the generated frequency distribution F2.

FIG. 11 illustrates an example of time-dependent variation of the frequency distribution F2 generated by the processing unit in the relay device according to the embodiment of the present disclosure. In FIG. 11, the horizontal axis represents the amplitude ratio A, and the vertical axis represents the frequency. FIG. 11 illustrates the frequency distributions F2a, F2b, F2c, and F2d. The frequency distribution F2a is the frequency distribution F2 of the amplitude ratio A when the abnormality of the transmission line 51 does not occur. The frequency distribution F2b is the frequency distribution F2 of the amplitude ratio A when the transmission line 51 is degraded. The frequency distribution F2c is the frequency distribution F2 of the amplitude ratio A when the degradation of the transmission line 51 is progressed. The frequency distribution F2d is the frequency distribution F2 of the amplitude ratio A when the transmission line 51 breaks.

Referring to FIG. 11, an average μ2 of the amplitude ratio A indicated by the frequency distribution F2 increases when the transmission line 51 degrades. When the transmission line 51 breaks, the average μ2 is a value near 1. Depending on the magnitude relationship between the characteristic impedance Z1 of the transmission line 51 and the load impedance Z2 of the communication device 111, the average μ2 may increase or reduce due to the degradation of the transmission line 51. In the communication system 301, the average μ2 is assumed to increase when the transmission line 51 degrades.

FIG. 12 illustrates another example of the time-dependent variation of the frequency distribution F2 generated by the processing unit in the relay device according to the embodiment of the present disclosure. In FIG. 12, the horizontal axis represents the amplitude ratio A, and the vertical axis represents the frequency. FIG. 12 illustrates the frequency distributions F2a and F2e. The frequency distribution F2e is the frequency distribution F2 of the amplitude ratio A when the transmission line 51 is short-circuited.

Referring to FIG. 12, the average μ2 indicated by the frequency distribution F2 is a value near 1 when the transmission line 51 is short-circuited.

FIG. 13 illustrates another example of the time-dependent variation of the frequency distribution F2 generated by the processing unit in the relay device according to the embodiment of the present disclosure. In FIG. 13, the horizontal axis represents the amplitude ratio A, and the vertical axis represents the frequency. FIG. 13 illustrates the frequency distributions F2a, F2b, and F2f. The frequency distribution F2f is the frequency distribution F2 of the amplitude ratio A when the special abnormality occurs in the transmission line 51.

Referring to FIG. 13, left-right symmetry of the shape of the frequency distribution F2 about the average μ2 is reduced when the special abnormality occurs in the transmission line 51.

As has been described with reference to FIGS. 11 to 13, the frequency distribution F2 varies when the abnormality occurs in the transmission line 51. Accordingly, the abnormality of the transmission line 51 can be determined based on the frequency distribution F2.

In more detail, when the processing unit 23 generates the frequency distribution F2, the processing unit 23 performs the determination process based on the time-dependent variation of statistics indicated by the frequency distribution F2. As an example, as the statistics indicated by the frequency distribution F2, the processing unit 23 calculates the average μ2 and a median m2 of the amplitude ratio A indicated by the frequency distribution F2 and performs the determination process based on the time-dependent variation of the average μ2 and the median m2.

For example, the storage unit 24 stores a reference distribution Fr2 and a reference average μ2a. The reference distribution Fr2 is the frequency distribution F2 of the amplitude ratio A when the abnormality of the transmission line 51 does not occur. The reference average μ2a is the average μ2 indicated by the reference distribution Fr2. The reference distribution Fr2 is generated in advance based on a plurality of amplitude ratios A calculated before the operation of the communication system 301.

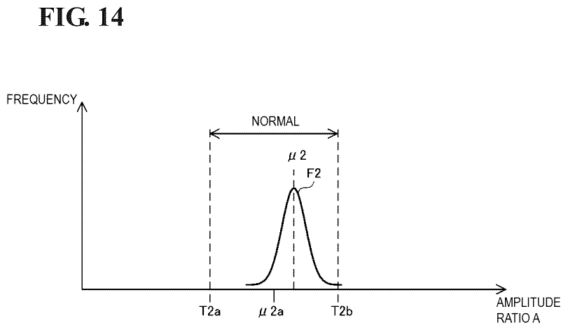

FIG. 14 illustrates an example of the frequency distribution F2 generated by the processing unit in the relay device according to the embodiment of the present disclosure. In FIG. 14, the horizontal axis represents the amplitude ratio A, and the vertical axis represents the frequency. Referring to FIG. 14, when the processing unit 23 generates the frequency distribution F2, the processing unit 23 compares the average μ2 indicated by the generated frequency distribution F2 with thresholds T2a and T2b set based on the reference distribution Fr2. The processing unit 23 also compares the average μ2 indicated by the frequency distribution F2 with the median m2 indicated by the frequency distribution F2.

For example, the threshold T2a is obtained by subtracting a predetermined value from the reference average μ2a, and the threshold T2b is obtained by adding a predetermined value to the reference average μ2a. The threshold T2a may be obtained by, for example, subtracting three times a standard deviation Sp of the reference distribution Fr2 from the reference average μ2a. The threshold T2b may be obtained by, for example, adding three times the standard deviation Sp to the reference average μ2a.

The processing unit 23 determines that the abnormality does not occur in the transmission line 51 when the average μ2 is the threshold T2a or greater and the threshold T2b or smaller and an absolute value D2 of the difference between the average μ2 and the median m2 is a predetermined threshold TD2 or smaller. Then, the processing unit 23 stores the determination results including the average μ2 in the storage unit 24.

The processing unit 23 may calculate, as the statistics indicated by the frequency distribution F2, the other statistics representing the shape of the frequency distribution F2 such as the standard deviation and the maximum value of the amplitude ratio A indicated by the frequency distribution F2 and use the calculated other statistics instead of the median m2.

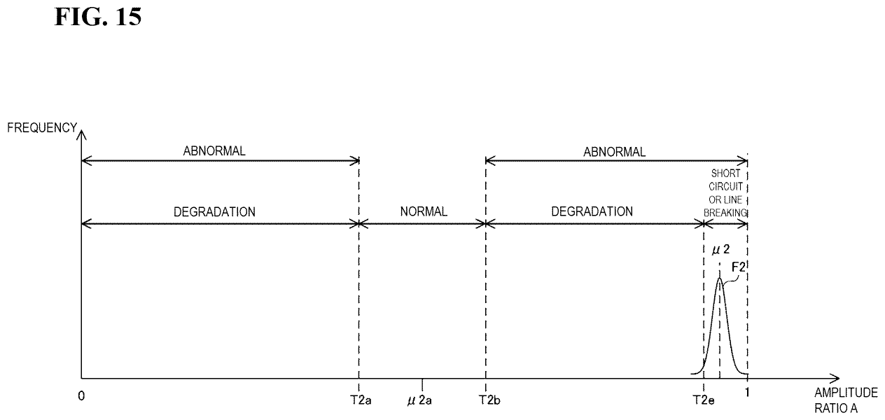

FIG. 15 illustrates another example of the frequency distribution F2 generated by the processing unit in the relay device according to the embodiment of the present disclosure. In FIG. 15, the horizontal axis represents the amplitude ratio A, and the vertical axis represents the frequency.

Referring to FIG. 15, the processing unit 23 determines that the abnormality occurs in the transmission line 51 when the average μ2 is smaller than the threshold T2a or greater than the threshold T2b.

In this case, the processing unit 23 further determines the types of the abnormality occurring in the transmission line 51 based on the frequency distribution F2. For example, the processing unit 23 determines breaking or a short circuit of the transmission line 51 and degradation of the transmission line 51 as the types of the abnormality occurring in the transmission line 51.

In more detail, the processing unit 23 compares the average μ2 with a predetermined threshold T2e. The threshold T2e is obtained by subtracting a predetermined value from 1.

The processing unit 23 determines that the transmission line 51 breaks or is short-circuited when the average μ2 is the threshold T2e or greater. Then, the processing unit 23 stores the determination results including the average μ2 in the storage unit 24.

The processing unit 23 determines that the transmission line 51 is degraded when the average μ2 is smaller than the threshold T2e. Then, the processing unit 23 stores the determination results including the average μ2 in the storage unit 24.

For example, the processing unit 23 determines the degree of progression of degradation of the transmission line 51 based on the time-dependent variation of the average μ2 indicated by the frequency distribution F2. In more detail, the processing unit 23 compares the calculated average μ2 with the average μ2 included in the previous determination results when the transmission line 51 is determined to be degraded. Then, the processing unit 23 determines the degree of progression based on the amount of variation by which the calculated average μ2 varies from the average μ2 included in the previous determination results.

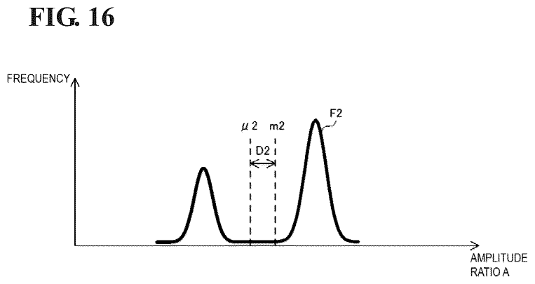

FIG. 16 illustrates another example of the frequency distribution F2 generated by the processing unit in the relay device according to the embodiment of the present disclosure. In FIG. 16, the horizontal axis represents the amplitude ratio A, and the vertical axis represents the frequency. Referring to FIG. 16, the processing unit 23 determines that the special abnormality occurs in the transmission line 51 when the absolute value D2 of the difference between the average μ2 and the median m2 is greater than the threshold TD2. Then, the processing unit 23 stores the determination results including the average μ2 and the median m2 in the storage unit 24.

### (Modification 2)

The processing unit 23 determines the abnormality of the transmission line 51 based on the time-dependent variation of the shape of the frequency distribution F2. For example, the processing unit 23 determines the abnormality of the transmission line 51 based on the correlation between the shape of the frequency distribution F2 and the shape of the reference distribution Fr2.

In more detail, when the processing unit 23 generates the frequency distribution F2, the processing unit 23 acquires the reference distribution Fr2 from the storage unit 24. Then, the processing unit 23 calculates a correlation coefficient C2 indicating the correlation between the generated frequency distribution F2 and the reference distribution Fr2 in accordance with expression (7) below.

$$[ Math . 7 ]$$

$$C 2 = \frac{Spq}{Sp \times Sq} = \frac{{\sum }_{i = 1}^{n} ( pi - μ 2 ) ( q i - μ 2 a )}{\sqrt{{\sum }_{i = 1}^{n} {( pi - μ 2 )}^{2} {\sum }_{i = 1}^{n} {( q i - μ 2 a )}^{2}}} \qquad ( 7 )$$

Where Spq is a covariance of the frequency distribution F2 and the reference distribution Fr2, Sp is a standard deviation of the frequency distribution F2, Sq is a standard deviation of the reference distribution Fr2, pi is a frequency of an amplitude ratio Ai in the frequency distribution F2, q is a frequency of an amplitude ratio Ai in the reference distribution Fr2, and n is the number of pieces of data of the amplitude ratio A included in the frequency distribution F2 and the number of pieces of data of the amplitude ratio A included in the reference distribution Fr2. For example, the amplitude ratio A in the frequency distribution F2 and the amplitude ratio A in the reference distribution Fr2 are relative. The amplitude ratio A in the frequency distribution F2 is corrected such that the position of the skirt of the frequency distribution F2 matches the position of the skirt of the reference distribution Fr2 or the median m2 of the frequency distribution F2 matches the median of the reference distribution Fr2.

When the correlation coefficient C2 is a predetermined threshold TC2 or greater, the processing unit 23 determines that the special abnormality does not occur in the transmission line 51. The threshold TC2 is a value of 0.2 to 1 appropriately set by the application. For example, the threshold TC2 may be 0.7. In contrast, when the correlation coefficient C2 is smaller than the predetermined threshold TC2, the processing unit 23 determines that the special abnormality occurs in the transmission line 51.

The processing unit 23 may perform the determination process based on time-dependent variation of an envelope representing the shape of the frequency distribution F2 instead of calculating the correlation coefficient C2. In more detail, the processing unit 23 determines whether the special abnormality occurs in the transmission line 51 based on a result of comparison between the envelope representing the shape of the frequency distribution F2 and an envelope representing the shape of the reference distribution Fr2.

For example, the processing unit 23 determines the abnormality of the transmission line 51 based on the frequency distributions F1 and F2. In more detail, the processing unit 23 executes determination example 1 and determination example 2. When it is determined that the abnormality occurs in the transmission line 51 in at least one of determination example 1 and determination example 2, an overall determination that the abnormality occurs in the transmission line 51 is made, and the user is notified of the result of the overall determination. The processing unit 23 may be configured not to execute one of determination example 1 and determination example 2.

### (Modification 3)

The processing unit 23 determines the types of the abnormality occurring in the transmission line 51 based on the frequency distributions F1 and F2.

Referring again to FIGS. 9 and 15, in more detail, the processing unit 23 determines that the transmission line 51 is short-circuited when the average μ1 is the threshold T1e or greater and the threshold T1f or smaller and the average μ2 is the threshold T2e or greater.

The processing unit 23 determines that the transmission line 51 is degraded when the average μ1 is the threshold T1e or greater and the threshold T1f or smaller and the average μ2 is smaller than the threshold T2e.

The processing unit 23 determines that the transmission line 51 breaks when the average μ1 is the threshold T1c or greater and the threshold T1d or smaller and the average μ2 is the threshold T2e or greater.

The processing unit 23 determines that the transmission line 51 is degraded when the average μ1 is the threshold T1c or greater and the threshold T1d or smaller and the average μ2 is smaller than the threshold T2e.

As has been described, with the configuration that determines the types of the abnormality occurring in the transmission line 51 based on the frequency distributions F1 and F2, a short circuit and degradation of the transmission line 51 can be determined and breaking and degradation of the transmission line 51 can be determined.

### (Modification 4)

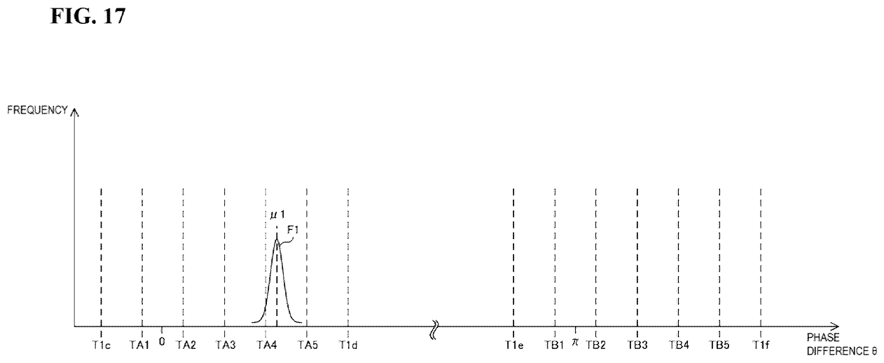

FIG. 17 illustrates another example of the frequency distribution F1 generated by the processing unit in the relay device according to the embodiment of the present disclosure. In FIG. 17, the horizontal axis represents the phase difference θ [rad], and the vertical axis represents the frequency.

Referring to FIG. 17, the processing unit 23 determines a line breaking position, a degraded position, and a short-circuited position in the transmission line 51 based on the frequency distribution F1.

In more detail, the processing unit 23 compares the average μ1 with thresholds TA, that is, thresholds TA1, TA2, TA3, TA4, and TA5 when the processing unit 23 determines that the transmission line 51 breaks or is degraded based on the results of comparison between the thresholds T1c and T1d and the average μ1 indicated by the frequency distribution F1.

The thresholds TA are the threshold T1c or greater and the threshold T1d or smaller. For example, the thresholds TA are values equally spaced in a range between the threshold T1c and the threshold T1d. That is, the threshold TA1 is a value obtained by adding a predetermined value M to the threshold T1c, the threshold TA2 is a value obtained by adding the predetermined value M to the threshold TA1, the threshold TA3 is a value obtained by adding the predetermined value M to the threshold TA2, the threshold TA4 is a value obtained by adding the predetermined value M to the threshold TA3, the threshold TA5 is a value obtained by adding the predetermined value M to the threshold TA4, and the threshold T1d is a value obtained by adding the predetermined value M to the threshold TA5. The processing unit 23 may compare the average μ1 with four or less thresholds TA or six or more thresholds TA. The thresholds TA are not necessarily equally spaced in the range between the threshold T1c and the threshold T1d.

For example, the storage unit 24 stores line breaking position information that indicates correspondences between the thresholds TA and the distance Lop from the end portion on the relay device 101 side to the line breaking position in the transmission line 51. The line breaking position information is created in advance based on the relationship between the phase difference θop and the distance Lop illustrated in FIG. 6.

The processing unit 23 identifies a threshold TA closest to the average μ1 out of five thresholds TA. The processing unit 23 obtains the distance Lop corresponding to the identified threshold TA from the line breaking position information in the storage unit 24. The processing unit 23 determines that the transmission line 51 breaks or is degraded at a position corresponding to the obtained distance Lop.

Furthermore, the processing unit 23 compares the average μ1 with thresholds TB, that is, thresholds TB1, TB2, TB3, TB4, and TB5 when the processing unit 23 determines that the transmission line 51 is short-circuited or degraded based on the results of comparison between the thresholds T1e and the T1f and the average μ1 indicated by the frequency distribution F1.

The thresholds TB are the threshold T1e or greater and the threshold T1f or smaller. For example, the thresholds TB are values equally spaced in a range between the threshold Tle and the threshold T1f. That is, the threshold TB1 is a value obtained by adding the predetermined value M to the threshold T1e, the threshold TB2 is a value obtained by adding the predetermined value M to the threshold TB1, the threshold TB3 is a value obtained by adding the predetermined value M to the threshold TB2, the threshold TB4 is a value obtained by adding the predetermined value M to the threshold TB3, the threshold TB5 is a value obtained by adding the predetermined value M to the threshold TB4, and the threshold T1f is a value obtained by adding the predetermined value M to the threshold TB5. The processing unit 23 may compare the average μ1 with four or less thresholds TB or six or more thresholds TB. The thresholds TB are not necessarily equally spaced in the range between the threshold T1e and the threshold T1f.

For example, the storage unit 24 stores short-circuited position information that indicates correspondences between the thresholds TB and the distance Lsh from the end portion on the relay device 101 side to the short-circuited position in the transmission line 51. The short-circuited position information is created in advance based on the relationship between the phase difference θsh and the distance Lsh illustrated in FIG. 6.

The processing unit 23 identifies a threshold TB closest to the average μ1 out of five thresholds TB. The processing unit 23 obtains the distance Lsh corresponding to the identified threshold TB from the short-circuited position information in the storage unit 24. The processing unit 23 determines that the transmission line 51 is short-circuited or degraded at a position corresponding to the obtained distance Lsh.

For example, the processing unit 23 determines the types of the abnormality occurring in the transmission line 51 in accordance with modification 3 described above and based on the frequency distribution F2. Thus, the line breaking position, the degraded position, and the short-circuited position of the transmission line 51 can be determined while the line breaking, the short circuit, and the degradation of the transmission line 51 are determined.

### [Flow of Operation]

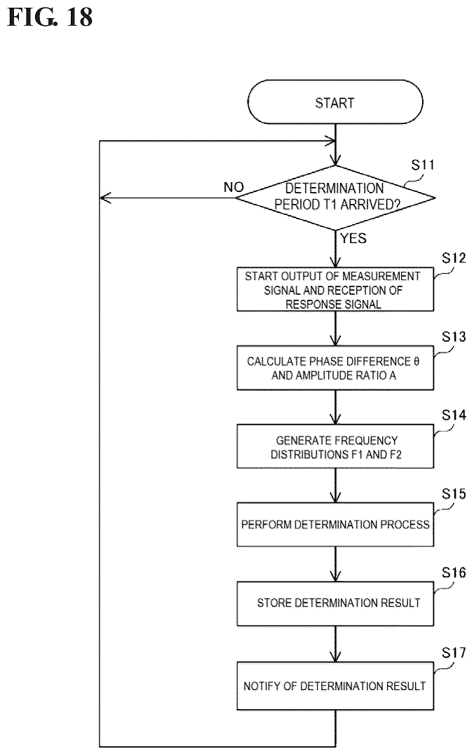

FIG. 18 is a flowchart defining an example of an operation procedure when the relay device according to the embodiment of the present disclosure performs the determination process.

Referring to FIG. 18, first, the relay device 101 waits for the arrival of the determination period T1 (NO in step S11). When the determination period T1 arrives (YES in step S11), the relay device 101 starts output of the measurement signal and reception of the response signal (step S12).

Next, the relay device 101 calculates the phase difference θ and the amplitude ratio A for each period of the measurement signal based on the amplitude and phase of the measurement signal and the amplitude and phase of the reflection signal included in the response signal (step S13).

Next, the relay device 101 generates the frequency distribution F1 of the phase difference θ in the determination period T1 and the frequency distribution F2 of the amplitude ratio A in the determination period T1 (step S14).

Next, the relay device 101 performs the determination process based on the frequency distributions F1 and F2 (step S15).

Next, the relay device 101 stores the determination results including the averages μ1 and μ2 in the storage unit 24 (step S16).

Next, when the relay device 101 determines that, for example, the abnormality occurs in the transmission line 51, the relay device 101 notifies the user of the determination results via the relay unit 10 and the communication device 111 (step S17).

Next, the relay device 101 waits for the arrival of a new determination period T1 (NO in step S11).

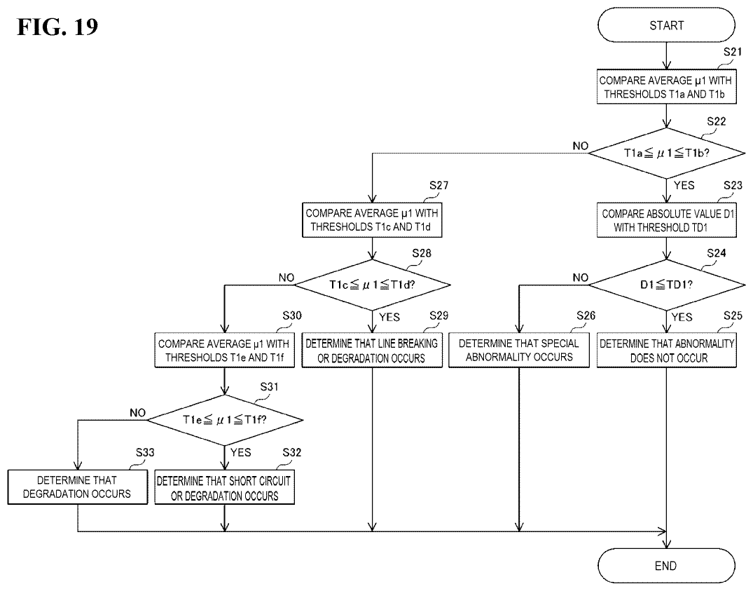

FIG. 19 is a flowchart defining the example of the operation procedure when the relay device according to the embodiment of the present disclosure performs the determination process. In FIG. 19, step S15 illustrated in FIG. 18 is detailed, and determination example 1 described above is illustrated in the flowchart.

Referring to FIG. 19, first, the relay device 101 compares the thresholds T1a and T1b and the average μ1 indicated by the frequency distribution F1 (step S21).

Next, when the average μ1 is the threshold T1a or greater and the threshold T1b or smaller (YES in step S22), the relay device 101 compares the absolute value D1 of the difference between the average μ1 and the median m1 with the threshold TD1 (step S23).

Next, when the absolute value D1 is the threshold TD1 or smaller (YES in step S24), the relay device 101 determines that the abnormality does not occur in the transmission line 51 (step S25).

In contrast, when the absolute value D1 is greater than the threshold TD1 (NO in step S24), the relay device 101 determines that the special abnormality occurs in the transmission line 51 (step S26).

When the average μ1 is smaller than the threshold T1a or greater the threshold T1b (NO in step S22), the relay device 101 compares the average μ1 with the thresholds Tlc and T1d (step S27).

Next, when the average μ1 is the threshold T1c or greater and the threshold T1d or smaller (YES in step S28), the relay device 101 determines that the transmission line 51 breaks or is degraded (step S29).

When the average μ1 is smaller than the threshold T1c or greater the threshold T1d (NO in step S28), the relay device 101 compares the average μ1 with the thresholds T1e and T1f (step S30).

Next, when the average μ1 is the threshold T1e or greater and the threshold T1f or smaller (YES in step S31), the relay device 101 determines that the transmission line 51 is short-circuited or degraded (step S32).

When the average μ1 is smaller than the threshold T1e or greater the threshold T1f (NO in step S31), the relay device 101 determines that the transmission line 51 is degraded (step S33).

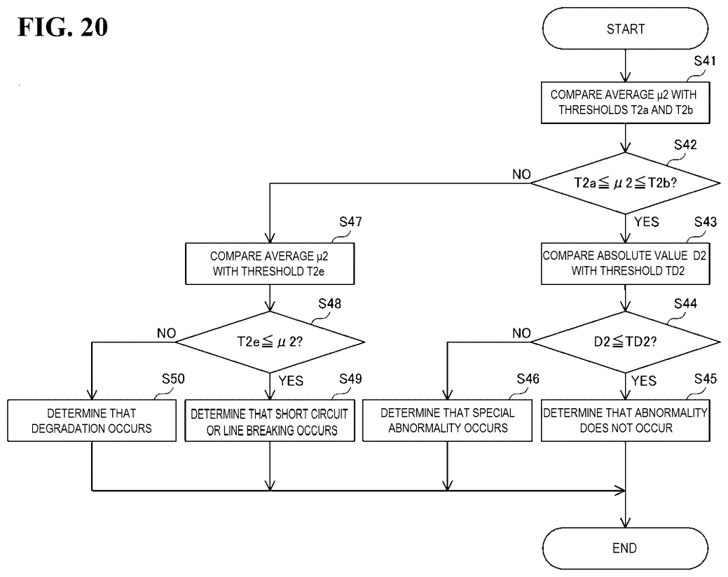

FIG. 20 is a flowchart defining the example of the operation procedure when the relay device according to the embodiment of the present disclosure performs the determination process. In FIG. 20, step S15 illustrated in FIG. 18 is detailed, and determination example 2 described above is illustrated in the flowchart.

Referring to FIG. 20, first, the relay device 101 compares the thresholds T2a and T2b and the average μ2 indicated by the frequency distribution F2 (step S41).

Next, when the average μ2 is the threshold T2a or greater and the threshold T2b or smaller (YES in step S42), the relay device 101 compares the absolute value D2 of the difference between the average μ2 and the median m2 with the threshold TD2 (step S43).

Next, when the absolute value D2 is the threshold TD2 or smaller (YES in step S44), the relay device 101 determines that the abnormality does not occur in the transmission line 51 (step S45).

In contrast, when the absolute value D2 is greater than the threshold TD2 (NO in step S44), the relay device 101 determines that the special abnormality occurs in the transmission line 51 (step S46).

When the average μ2 is smaller than the threshold T2a or greater the threshold T2b (NO in step S42), the relay device 101 compares the average μ2 with the thresholds T2e (step S47).

Next, when the average μ2 is the threshold T2e or greater (YES in step S48), the relay device 101 determines that the transmission line 51 is short-circuited or breaks (step S49).

When the average μ2 is smaller than the threshold T2e (NO in step S48), the relay device 101 determines that the transmission line 51 is degraded (step S50).

For example, in determining the types of the abnormality occurring in the transmission line 51 as in modification 3 described above, the relay device 101 executes the process of the flowchart illustrated in FIG. 19 and the process of the flowchart illustrated in FIG. 20. When the relay device 101 determines that the transmission line 51 breaks or is degraded in step S29 and the transmission line 51 is short-circuited or breaks in step S49, the relay device 101 makes the overall determination that the transmission line 51 breaks.

Furthermore, for example, when the relay device 101 determines that the transmission line 51 is short-circuited or degraded in step S32 and the transmission line 51 is short-circuited or breaks in step S49, the relay device 101 makes the overall determination that the transmission line 51 is short-circuited.

Furthermore, for example, as in modification 4 described above, in determining the line breaking position in the transmission line 51, the relay device 101 compares the average μ1 with a plurality of thresholds TA and obtains the distance Lop corresponding to the threshold TA closest to the average μ1 from the line breaking position information in step S29 illustrated in FIG. 19. Then, the relay device 101 determines that the transmission line 51 breaks or is degraded at the position corresponding to the obtained distance Lop.

Furthermore, for example, as in modification 4 described above, in determining the short-circuited position in the transmission line 51, the relay device 101 compares the average μ1 with a plurality of thresholds TB and obtains the distance Lsh corresponding to the threshold TB closest to the average μ1 from the line short-circuited position information in step S32 illustrated in FIG. 19. Then, the relay device 101 determines that the transmission line 51 is short-circuited or is degraded at the position corresponding to the obtained distance Lsh.

Although the relay device 101 is connected to the communication device 111 in a one-to-one manner via the transmission line 51 in the communication system 301 according to the embodiment of the present disclosure, this is not limiting. The relay device 101 may be connected to the plurality of communication devices 111 via a transmission line 51 of a bus-type in a one-to-many manner.

Although the relay device 101 performs the determination process in the communication system 301 according to the embodiment of the present disclosure, this is not limiting. A device in the communication system 301 different from the relay device 101 may perform the determination process. Specifically, for example, the communication device 111 may function as the determination device and perform the determination process.

Although the signal output unit 21 outputs the measurement signal to the transmission line 51 in the period during which the relay process is not performed by the relay unit 10 in the relay device 101 according to the embodiment of the present disclosure, this is not limiting. The signal output unit 21 may output the measurement signal to the transmission line 51 in the period during which the relay process is performed by the relay unit 10. In this case, for example, the relay device 101 performs frequency-division multiplexing on the communication signal and the measurement signal. In more detail, the signal output unit 21 generates the measurement signal of a different frequency band from that of the communication signal transmitted and received by the relay unit 10 and transmits the generated measurement signal to the transmission line 51.

Although the signal reception unit 22 receives from the transmission line 51 via the corresponding communication port 30 the response signal including the measurement signal output by the signal output unit 21 and the reflection signal being the signal resulting from the reflection of the measurement signal in the relay device 101 according to the embodiment of the present disclosure, this is not limiting. The signal reception unit 22 may receive the response signal not including the measurement signal. That is, the signal reception unit 22 may receives the reflection signal as the response signal. In more detail, for example, the signal output unit 21 outputs the measurement signal to the transmission line 51 via a directional coupler and the communication port 30. The signal reception unit 22 receives from the transmission line 51 the response signal not including the measurement signal via the communication port 30 and the directional coupler.

Although the processing unit 23 determines the types of the abnormality occurring in the transmission line 51 in the relay device 101 according to the embodiment of the present disclosure, this is not limiting. When the average μ1 is smaller than the threshold Tla or greater than the threshold T1b in determination example 1 described above, the processing unit 23 may determine that the abnormality occurs in the transmission line 51 while not determining the types of the abnormality. When the average μ2 is smaller than the threshold T2a or greater than the threshold T2b in determination example 2 described above, the processing unit 23 may determine that the abnormality occurs in the transmission line 51 while not determining the types of the abnormality.

Although the processing unit 23 determines the breaking of the transmission line 51, the short circuit of the transmission line 51, and the degradation of the transmission line 51 as the types of the abnormality occurring in the transmission line 51 in the relay device 101 according to the embodiment of the present disclosure, this is not limiting. The processing unit 23 may determine the special abnormality in the transmission line 51 while not determining the breaking of the transmission line 51, the short circuit of the transmission line 51, or the degradation of the transmission line 51.

Although the processing unit 23 calculates the phase difference θ and the amplitude ratio A as the evaluation value EV and performs the determination process based on the frequency distributions F1 and F2 in the relay device 101 according to the embodiment of the present disclosure, this is not limiting. The processing unit 23 may calculate an impedance of the transmission line 51, a reactance of the transmission line 51, or a resistance of the transmission line 51 as the evaluation value EV instead of the phase difference θ and the amplitude ratio A and perform the determination process based on a distribution of the calculated evaluation value EV.

Although the processing unit 23 calculates the evaluation value EV in the relay device 101 according to the embodiment of the present disclosure, this is not limiting. The processing unit 23 may obtain an amplitude of the reflection signal from the digital signal Ds3 as the evaluation value EV and perform the determination process based on a distribution of the obtained amplitude. The processing unit 23 may obtain a phase of the reflection signal from the digital signal Ds3 as the evaluation value EV and perform the determination process based on a distribution of the obtained phase.

Although the processing unit 23 generates the digital signal Ds3 indicating the reflection signal by subtracting the digital signals Ds1 from the digital signal Ds2 in the relay device 101 according to the embodiment of the present disclosure, this is not limiting. The signal reception unit 22 may generate, in response to the measurement signal from the signal output unit 21, an analog signal indicating the reflection signal by subtracting the measurement signal from the received response signal, generate the digital signal Ds3 by performing digital conversion on the generated analog signal, and output the generated digital signal Ds3 to the processing unit 23.

The above-described embodiment is exemplary in all respects and not limiting. It is intended that the scope of the present invention is indicated not by the above description but by the claims and includes all changes within the meaning and scope equivalent to the claims.

Each of the processes (each of the functions) according to the above-described embodiment is implemented by processing circuitry including one or a plurality of processors. In addition to the one or the plurality of processors described above, the processing circuitry may include, for example, an integrated circuit in which the following elements are combined with each other: one or a plurality of memory devices; a various types of analog circuits; and a various types of digital circuits. The one or the plurality of memory devices described above store a program (instructions) that causes the one or the plurality of processors to execute the above-described processes. The one or the plurality of processors may execute the processes in accordance with the program read from the one or the plurality of memory devices or may execute the processes in accordance with a logic circuit designed in advance so as to execute the processes. The processors may be various types of processors adequate for controlling a computer such as a central processing unit (CPU), a graphics processing unit (GPU), a digital signal processor (DSP), a field programmable gate array (FPGA), and an application specific integrated circuit (ASIC). The plurality of processors that are physically separated may cooperate with each other to execute the processes. For example, the processors mounted on a plurality of computers that are physically separated may cooperate with each other via networks such as a local area network (LAN), a wide area network (WAN), and the Internet to execute the processes. The above-described program may be installed in the memory devices via the networks from an external server or the like or may be stored in any of recording media such as a compact disc read-only memory (CD-ROM), a digital versatile disk read-only memory (DVD-ROM), and semiconductor memory, circulated in the stored states, and installed, from the recording media, in the memory devices.

The above description includes the features described in appendices below.

### Appendix 1

A determination device includes
a signal output unit configured to output, to a transmission line, a measurement signal having a frequency component,
a signal reception unit configured to receive, from the transmission line, a response signal including a signal resulting from reflection of the measurement signal,
an acquisition unit configured to acquire a plurality of evaluation values based on at least one of an amplitude and a phase of the response signal received by the signal reception unit, and
a determination unit configured to determine an abnormality of the transmission line based on a distribution of the evaluation values acquired by the acquisition unit.

The determination unit determines a degree of progression of degradation of the transmission line based on time-dependent variation of the distribution.

### Appendix 2

A determination device includes
processing circuitry.

The processing circuitry
configured to output, to a transmission line, a measurement signal having a frequency component,
configured to receive, from the transmission line, a response signal including a signal resulting from reflection of the measurement signal,
configured to acquire a plurality of evaluation values based on at least one of an amplitude and a phase of the received response signal, and
configured to determine an abnormality of the transmission line based on a distribution of the acquired evaluation values.

### REFERENCE SIGNS LIST

10 relay unit
20 determination processing unit
21 signal output unit
22 signal reception unit
23 processing unit (acquisition unit, determination unit)
24 storage unit
30 communication port
51 transmission line
101 relay device
111 communication device
301 communication system
F1, F1a, F1b, F1c, F1d, F1e, F1f, F2, F2a, F2b, F2c, F2d, F2e, F2f frequency distribution

1. A determination device comprising:
a signal output circuit configured to output, to a transmission line, a measurement signal having a frequency component;
a signal reception circuit configured to receive, from the transmission line, a response signal including a signal resulting from reflection of the measurement signal;
an acquisition circuit configured to acquire a plurality of evaluation values based on at least one of an amplitude and a phase of the response signal received by the signal reception circuit; and
a determination circuit configured to determine an abnormality of the transmission line based on a distribution of the evaluation values acquired by the acquisition circuit.

2. The determination device according to claim 1,
wherein the determination circuit determines the abnormality of the transmission line based on time-dependent variation of a statistic indicated by the distribution.

3. The determination device according to claim 1,
wherein the determination circuit determines the abnormality of the transmission line based on a correlation between the distribution and a predetermined distribution.

4. The determination device according to claim 1,
wherein the determination circuit further determines a type of the abnormality occurring in the transmission line based on the distribution.

5. The determination device according to claim 4,
wherein the determination circuit determines, as the type of the abnormality occurring in the transmission line, at least one of breaking of the transmission line, a short circuit of the transmission line, and degradation of the transmission line.

6. The determination device according to claim 1,
wherein the acquisition circuit acquires first evaluation values being the evaluation values based on the amplitude and second evaluation values being the evaluation values based on the phase, and
wherein the determination circuit determines the abnormality of the transmission line based on a distribution of the first evaluation values and a distribution of the second evaluation values.

7. The determination device according to claim 6,
wherein the determination circuit determines, as types of the abnormality occurring in the transmission line, the breaking of the transmission line, the short circuit of the transmission line, and the degradation of the transmission line based on the distribution of the first evaluation values and the distribution of the second evaluation values.

8. The determination device according to claim 6,
wherein the determination circuit determines a position of the abnormality occurring in the transmission line based on the distribution of the second evaluation values.

9. A determination method comprising:
outputting, to a transmission line, a measurement signal having a frequency component;
receiving, from the transmission line, a response signal including a signal resulting from reflection of the measurement signal;
acquiring a plurality of evaluation values based on at least one of an amplitude and a phase of the received response signal; and
determining an abnormality of the transmission line based on a distribution of the acquired evaluation values.
